(19) United States
(12) Patent Application Publication
(10) Pub. No.: US 2025/0392259 A1
(43) Pub. Date: Dec. 25, 2025

(54) OPERATIONAL AMPLIFIER AND CURRENT INTEGRATOR USING THE SAME

(71) Applicant: LITE-ON SINGAPORE PTE. LTD., Singapore (SG)

(72) Inventor: Yoshio Nishida, Singapore (SG)

(21) Appl. No.: 19/051,132

(22) Filed: Feb. 11, 2025

(30) Foreign Application Priority Data
Jun. 19, 2024 (SG) 10202401790T

(51) Int. Cl. H03F 1/02; H03F 3/45

(52) U.S. Cl. CPC H03F 1/0205; H03F 3/45273; H03F 2200/264; H03F 2200/297; H03F 2200/61

(57) ABSTRACT

An operational amplifier and a current integrator using the same are provided. The operational amplifier includes an input stage, a current mirror, and a cascode circuit. The input stage includes a first input transistor and a plurality of second input transistors. The current mirror includes a first mirror circuit and a plurality of second mirror circuits. The cascode circuit is connected to the current mirror and the input stage, and the cascode circuit includes a first cascode branch and a plurality of second cascode branches. The first cascode branch is connected to the first input transistor and the first mirror circuit. The plurality of second cascode branches are respectively connected to the plurality of second input transistors and respectively connected to the plurality of second mirror circuits. A plurality of output terminals are located between the plurality of second cascode branches and the plurality of second mirror circuits.

### CROSS-REFERENCE TO RELATED PATENT APPLICATION

This application claims the benefit of priority to the Singapore Provisional Patent Application Ser. No. 10202401790T, filed on Jun. 19, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to electronic devices, and more particularly to an operational amplifier and a current integrator using the same.

### BACKGROUND OF THE DISCLOSURE

In the related art, the ambient light sensor detects and processes various elements of light, such as RGB primary colors, infrared light, and dark light, in parallel. To handle multiple photodiode currents (e.g., five) simultaneously, the ambient light sensor systematically requires multiple current integrators and, consequently, multiple operational amplifiers.

The front-end operational amplifier is the most critical component in terms of noise, speed, and linearity. Consequently, it consumes a significant amount of power and occupies considerable area.

### SUMMARY OF THE DISCLOSURE

In response to the above-referenced technical inadequacies, the present disclosure provides an operational amplifier and a current integrator using the same capable of performing multiple current integrations concurrently with less power consumption and smaller area.

In order to solve the above-mentioned problems, one of the technical aspects adopted by the present disclosure is to provide an operational amplifier, including an input stage, a current mirror, and a cascode circuit. The input stage includes a first input transistor having a first input terminal and a plurality of second input transistors having a plurality of second input terminals, and the first input transistor and the plurality of second input transistors are connected to a current source. The current mirror includes a first mirror circuit and a plurality of second mirror circuits. The cascode circuit is connected to the current mirror and the input stage, and the cascode circuit includes a first cascode branch and a plurality of second cascode branches. The first cascode branch is connected to the first input transistor and the first mirror circuit. The plurality of second cascode branches are respectively connected to the plurality of second input transistors and respectively connected to the plurality of second mirror circuits. A plurality of output terminals are located between the plurality of second cascode branches and the plurality of second mirror circuits.

In order to solve the above-mentioned problems, another one of the technical aspects adopted by the present disclosure is to provide a current integrator, including an operational amplifier, a plurality of integration capacitors and a plurality of reset switches. The operational amplifier includes an input stage, a current mirror, and a cascode circuit. The input stage includes a first input transistor having a first input terminal connected to a reference voltage and a plurality of second input transistors having a plurality of second input terminals, and the first input transistor and the plurality of second input transistors are connected to a current source. The current mirror includes a first mirror circuit and a plurality of second mirror circuits. The cascode circuit is connected to the current mirror and the input stage, and the cascode circuit includes a first cascode branch and a plurality of second cascode branches. The first cascode branch is connected to the first input transistor and the first mirror circuit. The plurality of second cascode branches are respectively connected to the plurality of second input transistors and respectively connected to the plurality of second mirror circuits. A plurality of output terminals are located between the plurality of second cascode branches and the plurality of second mirror circuits. The plurality of integration capacitors are respectively connected between the plurality of second input terminals and the plurality of output terminals. The plurality of reset switches are respectively connected to the plurality of integration capacitors in parallel between the plurality of second input terminals and the plurality of output terminals.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a functional block diagram of an operational amplifier according to one embodiment of the present disclosure;

FIG. 2 is a circuit diagram of an operational amplifier according to one embodiment of the present disclosure;

FIG. 3 is a schematic view of a current integrator according to one embodiment of the present disclosure; and

FIG. 4 shows simulation results of a conventional current integrator and the current integrator according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

An object of the present disclosure is to provide a unique operational amplifier which may perform multiple current integrations concurrently with less power consumption and smaller area by sharing a common portion of an input stage while providing multiple inputs and outputs.

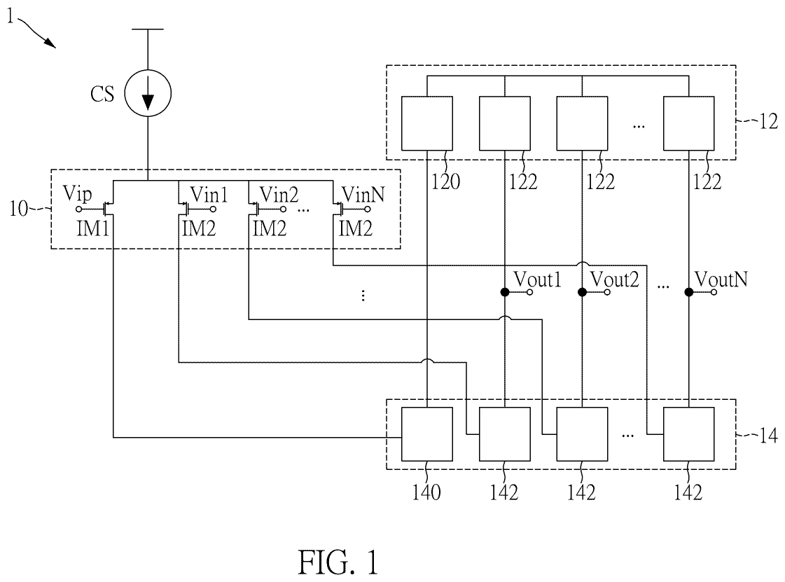

FIG. 1 is a functional block diagram of an operational amplifier according to one embodiment of the present disclosure. Referring to FIG. 1, one embodiment of the present disclosure provides an operational amplifier 1, including an input stage 10, a current mirror 12, and a cascode circuit 14.

The input stage 10 includes a first input transistor IM1 having a first input terminal Vip and a plurality of second input transistors IM2 having a plurality of second input terminals Vin1, Vin2, . . . . VinN, and the first input transistor IM1 and the plurality of second input transistors IM2 are connected to a current source CS. The first input terminal Vip may be shared with the second input transistors IM2 to form differential pairs.

The current mirror 12 includes a first mirror circuit 120 and a plurality of second mirror circuits 122. The cascode circuit 14 is connected to the current mirror 12 and the input stage 10, and the cascode circuit 14 includes a first cascode branch 140 and a plurality of second cascode branches 142.

The first cascode branch 140 is connected to the first input transistor IM1 and the first mirror circuit 120. The plurality of second cascode branches 142 are respectively connected to the plurality of second input transistors IM2 and respectively connected to the plurality of second mirror circuits 122, and a plurality of output terminals Vout1, Vout2, . . . , VoutN are located between the plurality of cascode branches 142 and the plurality of second mirror circuits 122.

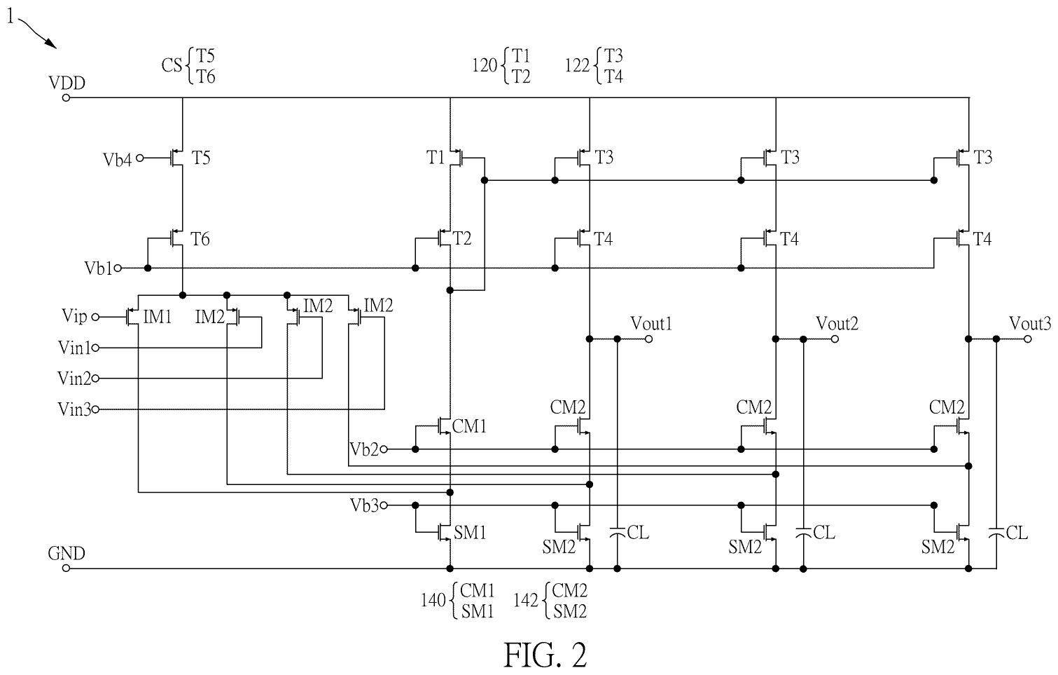

The above-mentioned FIG. 1 only briefly describes the basic structure of the operational amplifier 1 of the present disclosure. The details of each component will be described below with reference to FIG. 2.

FIG. 2 is a circuit diagram of an operational amplifier according to one embodiment of the present disclosure. Referring to FIG. 2, in the operational amplifier 1, N is 3 for example, which means there are three second input terminals Vin1, Vin2, Vin3 and three output terminals Vout1, Vout2, Vout3. Accordingly, the input stage 10 includes three second input transistors IM2, the current mirror 12 includes three second mirror circuits 122, and the cascode circuit 14 includes three second cascode branches 142.

The first input transistor IM1 may be shared with the three second input transistors IM2 to form differential pairs, such that input voltage signals can be converted into current signals.

The first cascode branch 140 may include a first cascode transistor CM1 and a first current source transistor SM1, and each of the second cascode branches 142 may include a second cascode transistor CM2 and a second current source transistor SM2.

The first mirror circuit 120 may include a first transistor T1 and a second transistor T2, and each of the second mirror circuits 122 may include a third transistor T3 and a fourth transistor T4.

The first input transistor IM1 may be a P-channel metal-oxide-semiconductor field effect transistor (PMOSFET). A source of the first input transistor IM1 is connected to the current source CS that includes transistors T5 and T6. The transistor T5 and the transistor T6 may be PMOSFETs, a source of the transistor T5 is connected to the common voltage source VDD, a drain of the transistor T5 is connected to a source of the transistor T6, a gate of the transistor T5 is connected to a fourth bias voltage Vb4, a drain of the transistor T6 is connected to the first input transistor IM1 and the plurality of second input transistors IM2, and a gate of the transistor T6 is connected to a first bias voltage Vb1. Moreover, a drain of the first input transistor IM1 is connected between the first cascode transistor CM1 and the first current source transistor SM1, and a gate of the first input transistor IM1 may be the first input terminal Vip, which can be used as a non-inverting input terminal of the operation amplifier 1. The current source CS may provide a bias current for the three differential pair circuits consisting of the first input transistor IM1 and the three second input transistors IM2.

Furthermore, each of the second input transistors IM2 may also be PMOSFETs, a source of the second input transistor IM2 is connected to the current source CS, a drain of the second input transistor IM2 is connected between a corresponding one of the second cascode transistors CM2 and a corresponding one of the second current source transistors SM2, and a gate of the second input transistor IM2 may be one of the second input terminals Vin1, Vin2, Vin3.

The first transistor T1 and the second transistor T2 may be PMOSFETs, and a source of the first transistor T1 is connected to a common voltage source VDD, a drain of the first transistor T1 is connected to a source of the second transistor T2, a gate of the first transistor T1 is connected between the first cascode transistor CM1 and a drain of the second transistor T2, a gate of the second transistor T2 is connected to the first bias voltage Vb1.

Moreover, each of the third transistors T3 may be a PMOSFET and has a drain, a source connected to the common voltage source VDD, and a gate connected to the gate of the first transistor T1 and the drain of the second transistor T2. Each of the fourth transistors T4 may be a PMOSFET and has a source connected to the drain of the corresponding third transistor T3, a drain connected to one of the output terminals Vout1, Vout2 and Vout3 and one of the second cascode transistors CM2, and a gate connected to the first bias voltage Vb1. The first transistor T1 and the second transistor T2, connected as shown, form a wide swing cascode current mirror whose current is reflected to one of the third transistors T3.

The first cascode transistor CM1 may be an N-channel metal-oxide-semiconductor field effect transistor (NMOSFET), a source of the first cascode transistor CM1 is connected to the drain of the first input transistor IM1, a drain of the first cascode transistor CM1 is connected to the drain of the second transistor T2, and a gate of the first cascode transistor CM1 is connected to a second bias voltage Vb2.

The first current source transistor SM1 may be an NMOSFET and has a source connected to a ground terminal GND, a drain connected to the drain of the first input transistor IM1 and the source of the first cascode transistor CM1, and a gate connected to a third bias voltage Vb3.

Similarly, each of the second cascode transistors CM2 may be an NMOSFET and has a source connected to the drain of one of the second input transistors IM2, a drain connected to the drain of one of the fourth transistors T4 and one of the output terminals Vout1, Vout2 and Vout3, and a gate connected to the second bias voltage Vb2. Each of the second current source transistors SM2 may also be an NMOSFET and has a source connected to the ground terminal GND, a drain connected to the drain of one of the second input transistors IM2 and the source of one of the second cascode transistors CM2, a gate connected to the third bias voltage Vb3.

In the present embodiment, the first cascode transistor CM1 and the second cascode transistors CM2 are biased into saturation by the second bias voltage Vb2 and function as current buffers, and the first current source transistor SM1 and the second current source transistors SM2 controlled by the third bias voltage Vb3 form current sources used to provide currents for the first cascode transistor CM1 and the second cascode transistor CM2, respectively. Furthermore, the operational amplifier 1 further includes a load capacitor CL, and the load capacitor CL is connected between one of the output terminals Vout1, Vout2 and Vout3 and the ground terminal GND. In some embodiments, each of the output terminals Vout1, Vout2 and Vout3 is connected to ground terminal GND through a load capacitor CL.

During an operation of the operation amplifier 1, the first input transistor IM1 and the second input transistors IM2 respectively convert the input voltage signals into current signals, which are then “folded” into the cascode stage. That is, the first cascode transistor CM1 and the second cascode transistors CM2 provide high output impedance. The current signals from the cascode stage then enters the current mirror 12 that convert the current signals back into voltage signals, and the voltage signals are output from the output terminals output terminals Vout1, Vout2 and Vout3 without being interfered with one another.

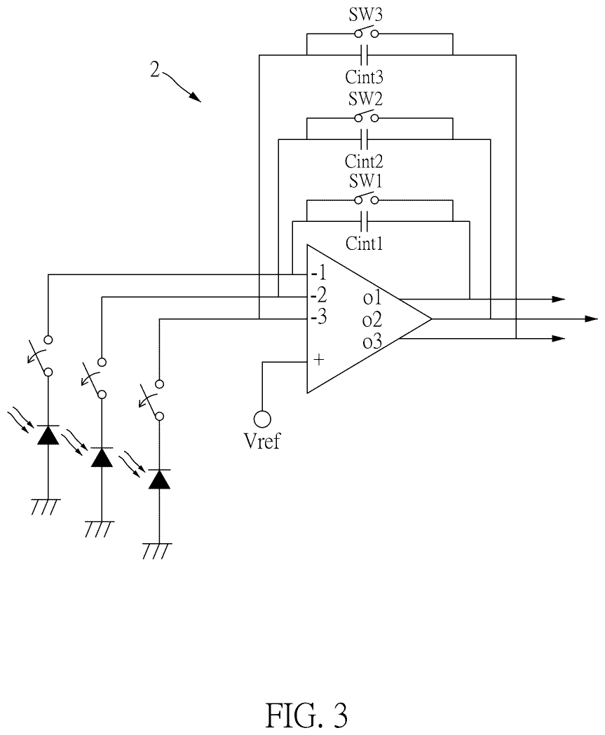

FIG. 3 is a schematic view of a current integrator according to one embodiment of the present disclosure. Referring to FIG. 3, another embodiment of the present disclosure further provides a current integrator 2, including the operational amplifier 1 of FIG. 2, integration capacitors Cint1, Cint2 and Cint3 and reset switches SW1, SW2 and SW3. It should be noted that in the present embodiment, the first input terminal Vip is denoted as “+” (non-inverting input terminal), the second input terminals Vin1, Vin2 and Vin3 are denoted as “−1”, “−2” and “−3”, respectively, and the output terminals Vout1, Vout2 and Vout3 are denoted as “o1”, “o2” and “o3”. Furthermore, the first input terminal “+” is connected to a reference voltage Vref. Reference voltage Vref may be a voltage of ground (0V) or a specific bias voltage depending on the design requirements, which ensures that the operational amplifier 1 operates within its linear range and provides a stable reference point for the integration phase.

The integration capacitors Cint1, Cint2 and Cint3 are respectively connected between the second input terminals “−1”, “−2” and “−3” and the output terminals “o1”, “o2” and “o3”. Similar to the integration capacitors Cint1, Cint2 and Cint3, the reset switches SW1, SW2 and SW3 are respectively connected to the integration capacitors Cint1, Cint2 and Cint3 in parallel between the second input terminals “−1”, “−2” and “−3” and the output terminals “o1”, “o2” and “o3”.

The reset switches SW1, SW2 and SW3 may be controlled by multiple control signals (e.g., from a control circuit such as a controller, a processor, or a microcontroller) to be turned on and off.

The reset switches SW1, SW2 and SW3 can be used to discharge the integration capacitors Cint1, Cint2 and Cint3, allowing a new integration cycle to begin. When the reset switches SW1, SW2 and SW3 are closed, the integration capacitor Cint1, Cint2 and Cint3 discharges, resetting the voltage to their initial state, thereby ensuring that each integration cycle starts from the same point and preventing cumulative errors.

The second input terminals “−1”, “−2” and “−3” can be connected to photodiodes, so as to receive photodiode currents as input currents. When the reset switches SW1, SW2 and SW3 are open, as the photodiode currents flow through the integration capacitors Cint1, Cint2 and Cint3, respectively, the voltage across each of the integration capacitors Cint1, Cint2 and Cint3 increases over time, and the voltage change is proportional to the integrated photodiode current, allowing for accurate measurement of the photodiode currents. The operational amplifier 1 in the current integrator 2 can be configured as an inverting integrator circuit to amplify and stabilize the input signals.

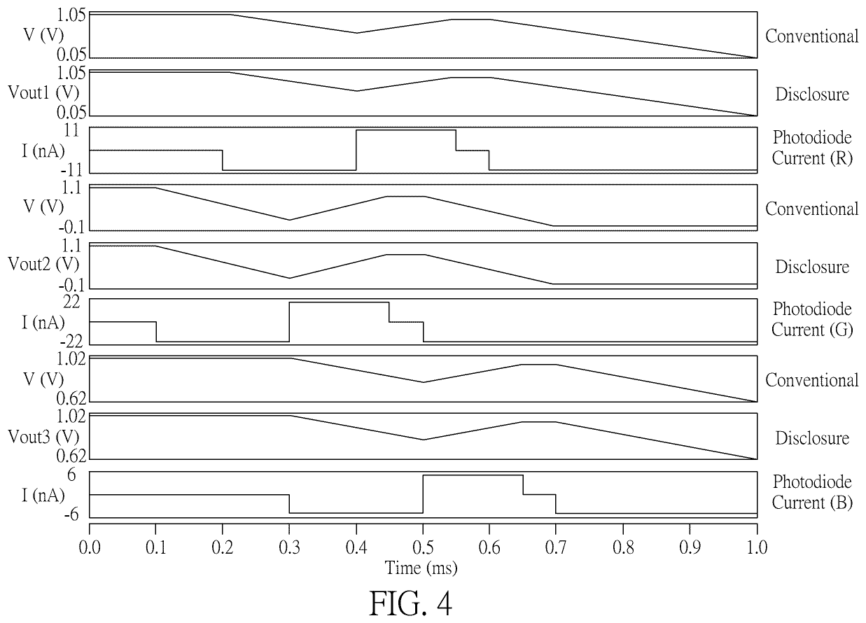

FIG. 4 shows simulation results of a conventional current integrator which uses a conventional operational amplifier and the current integrator according to one embodiment of the present disclosure. Referring to FIG. 4, three types of photodiode currents (e.g., red, green and blue, RGB) are input concurrently to the conventional current integrator and the current integrator 2 provided by the present disclosure in a simulation scenario.

As shown in FIG. 4, outputs of the conventional current integrator using the conventional operational amplifier and outputs of the current integrator 2 provided by the present disclosure are obtained. The simulation results show that outputs of the current integrator 2 utilizing the operational amplifier 1 are similar to the outputs of the conventional current integrator. However, the conventional integrator needs three conventional amplifiers that consume a total current of 18.5 uA, according to a simulation using UMC 0.18 um CMOS process model. On the other hand, the current integrator 2 utilizing the operational amplifier 1 merely consumes a total current of 12.2 uA. It can be seen from FIG. 4 that the operational amplifier and the current integrator using the same are capable of performing multiple current integrations concurrently with less power consumption and smaller area.

### Beneficial Effects of the Embodiments

In conclusion, in the operational amplifier and the current integrator using the same provided by the present disclosure, multiple current integrations can be performed concurrently with less power consumption and smaller area. Furthermore, the reference voltage provided to the first input terminal can be regulated to ensure that the operational amplifier operates within its linear range and provides a stable reference point for the integration phase.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An operational amplifier, comprising:
an input stage comprising a first input transistor having a first input terminal and a plurality of second input transistors having a plurality of second input terminals, wherein the first input transistor and the plurality of second input transistors are connected to a current source;
a current mirror comprising a first mirror circuit and a plurality of second mirror circuits;
a cascode circuit connected to the current mirror and the input stage, wherein the cascode circuit comprises:
a first cascode branch connected to the first input transistor and the first mirror circuit; and
a plurality of second cascode branches respectively connected to the plurality of second input transistors and respectively connected to the plurality of second mirror circuits,
wherein a plurality of output terminals are located between the plurality of second cascode branches and the plurality of second mirror circuits.

2. The operational amplifier according to claim 1, wherein the first cascode branch comprises a first cascode transistor and a first current source transistor, each of the second cascode branches comprises a second cascode transistor and a second current source transistor.

3. The operational amplifier according to claim 2, wherein the first mirror circuit comprises a first transistor and a second transistor, and each of the second mirror circuits comprises a third transistor and a fourth transistor.

4. The operational amplifier according to claim 3, wherein the first input transistor has a first terminal connected to the current source, a second terminal connected between the first cascode transistor and the first current source transistor, and a third terminal being the first input terminal;
wherein each of the second input transistors has a first terminal connected to the current source, a second terminal connected between one of the second cascode transistors and one of the second current source transistors, and a third terminal being one of the second input terminals.

5. The operational amplifier according to claim 4, wherein the first transistor has a first terminal, a second terminal and a third terminal, the second transistor has a first terminal, a second terminal and a third terminal, the first terminal of the first transistor is connected to a common voltage source, the second terminal of the first transistor is connected to the first terminal of the second transistor, the third terminal of the first transistor is connected between the first cascode transistor and the second terminal of the second transistor, the third terminal of the second transistor is connected to a first bias voltage.

6. The operational amplifier according to claim 5, wherein each of the third transistors has a first terminal connected to the common voltage source, a second terminal, and a third terminal connected to the third terminal of the first transistor and the second terminal of the second transistor, wherein each of the fourth transistors has a first terminal connected to the second terminal of the corresponding third transistor, a second terminal connected to one of the output terminals and one of the second cascode transistors, and a third terminal connected to the first bias voltage.

7. The operational amplifier according to claim 6, wherein the first cascode transistor has a first terminal connected to the second terminal of the first input transistor, a second terminal connected to the second terminal of the second transistor, and a third terminal connected to a second bias voltage; wherein the first current source transistor has a first terminal connected to a ground terminal, a second terminal connected to the first terminal of the first cascode transistor, a third terminal connected to a third bias voltage.

8. The operational amplifier according to claim 7, wherein each of the second cascode transistors has a first terminal connected to the second terminal of one of the second input transistors, a second terminal connected to the second terminal of one of the fourth transistors and one of the output terminals, and a third terminal connected to the second bias voltage;
wherein each of the second current source transistors has a first terminal connected to the ground terminal, a second terminal connected to the first terminal of one of the second cascode transistors, a third terminal connected to the third bias voltage.

9. The operational amplifier according to claim 8, further comprising a load capacitor, the load capacitor is connected between one of the output terminals and the ground terminal.

10. The operational amplifier according to claim 9, wherein the first input transistor, the second input transistors, the first transistor, the second transistor, the third transistors and the fourth transistors are P-channel metal-oxide-semiconductor field effect transistors (MOSFETs), and the first cascode transistor, the first current source transistor, the second cascode transistors and the second current source transistors are N-channel MOSFETs.

11. A current integrator, comprising:
an operational amplifier, comprising:
an input stage comprising a first input transistor having a first input terminal connected to a reference voltage and a plurality of second input transistors having a plurality of second input terminals, wherein the first input transistor and the plurality of second input transistors are connected to a current source;
a current mirror comprising a first mirror circuit and a plurality of second mirror circuits;
a cascode circuit connected to the current mirror and the input stage, wherein the cascode circuit comprises:
a first cascode branch connected to the first input transistor and the first mirror circuit; and
a plurality of second cascode branches respectively connected to the plurality of second input transistors and respectively connected to the plurality of second mirror circuits, wherein a plurality of output terminals are located between the plurality of second cascode branches and the plurality of second mirror circuits;
a plurality of integration capacitors respectively connected between the plurality of second input terminals and the plurality of output terminals;
a plurality of reset switches respectively connected to the plurality of integration capacitors in parallel between the plurality of second input terminals and the plurality of output terminals.

12. The current integrator according to claim 11, wherein the first cascode branch comprises a first cascode transistor and a first current source transistor, each of the second cascode branches comprises a second cascode transistor and a second current source transistor.

13. The current integrator according to claim 12, wherein the first mirror circuit comprises a first transistor and a second transistor, and each of the second mirror circuits comprises a third transistor and a fourth transistor.

14. The current integrator according to claim 13, wherein the first input transistor has a first terminal connected to the current source, a second terminal connected between the first cascode transistor and the first current source transistor, and a third terminal being the first input terminal;
wherein each of the second input transistors has a first terminal connected to the current source, a second terminal connected between one of the second cascode transistors and one of the second current source transistors, and a third terminal being one of the second input terminals.

15. The current integrator according to claim 14, wherein the first transistor has a first terminal, a second terminal and a third terminal, the second transistor has a first terminal, a second terminal and a third terminal, the first terminal of the first transistor is connected to a common voltage source, the second terminal of the first transistor is connected to the first terminal of the second transistor, the third terminal of the first transistor is connected between the first cascode transistor and the second terminal of the second transistor, the third terminal of the second transistor is connected to a first bias voltage.

16. The current integrator according to claim 15, wherein each of the third transistors has a first terminal connected to the common voltage source, a second terminal, and a third terminal connected to the third terminal of the first transistor and the second terminal of the second transistor, wherein each of the fourth transistors has a first terminal connected to the second terminal of the corresponding third transistor, a second terminal connected to one of the output terminals and one of the second cascode transistors, and a third terminal connected to the first bias voltage.

17. The current integrator according to claim 16, wherein the first cascode transistor has a first terminal connected to the second terminal of the first input transistor, a second terminal connected to the second terminal of the second transistor, and a third terminal connected to a second bias voltage;
wherein the first current source transistor has a first terminal connected to a ground terminal, a second terminal connected to the second terminal of the first input transistor and the first terminal of the first cascode transistor, a third terminal connected to a third bias voltage.

18. The current integrator according to claim 17, wherein each of the second cascode transistors has a first terminal connected to the second terminal of one of the second input transistors, a second terminal connected to the second terminal of one of the fourth transistors and one of the output terminals, and a third terminal connected to the second bias voltage;
wherein each of the second current source transistors has a first terminal connected to the ground terminal, a second terminal connected to the second terminal of one of the second input transistor and the first terminal of one of the second cascode transistors, a third terminal connected to the third bias voltage.

19. The current integrator according to claim 18, further comprising a load capacitor, the load capacitor is connected between one of the output terminals and the ground terminal.

20. The current integrator according to claim 19, wherein the first input transistor, the second input transistors, the first transistor, the second transistor, the third transistors and the fourth transistors are P-channel metal-oxide-semiconductor field effect transistors (MOSFETs), and the first cascode transistor, the first current source transistor, the second cascode transistors and the second current source transistors are N-channel MOSFETs.
